(19) United States
(12) Patent Application Publication
(10) Pub. No.: US 2017/0089972 A1
(43) Pub. Date: Mar. 30, 2017

(54) APPARATUS AND METHOD FOR TESTING UTILITY LINE POLES

(71) Applicant: Utility Solutions, Inc., Hickory, NC (US)

(72) Inventors: Eugene H. Wood, Hickory, NC (US); Matthew G. Nolte, Hickory, NC (US)

(21) Appl. No.: 14/867,566

(22) Filed: Sep. 28, 2015

(51) Int. Cl. G01R 31/14

(52) U.S. Cl. CPC G01R 31/14

(57) ABSTRACT

An apparatus and method for testing utility line poles is disclosed. The apparatus including at least one sensor electrode electrically connected to a high voltage generator; a battery electrically connected to the high voltage generator; and a visual display configured to provide a user with a visual indication of a condition of the insulating pole being tested. The high voltage generator increases a voltage supplied by the battery to a pre-determined voltage and supplies the pre-determined voltage to the at least one sensor electrode. The insulating pole is pressed into contact with the at least one sensor electrode during testing to impart the pre-determined voltage into the insulating pole.

### BACKGROUND OF THE INVENTION

This invention relates generally to tools for repair and maintenance of electrical distribution and transmission components, and more particularly to devices for testing insulating poles such as utility line poles and/or “hotsticks”.

Utility line poles are known for use in repair or maintenance of high-voltage electrical conductors (e.g. overhead transmission lines). The poles are made of an insulating material and are commonly referred to as “hot sticks”.

The accessibility of electrical power distribution lines varies substantially because the lines are installed both above ground at various elevations and below ground in underground electric power distribution systems. As a result of such a highly diverse and non-uniform manner in which the electrical power distribution lines are positioned and mounted, the access distances between the electrical power distribution lines and the user vary substantially. For example, an above ground electrical power distribution line may be 10 feet or more from the user thus requiring a pole of at least 10 feet in length in order to reach the line. On the other hand, a below ground electrical power distribution line may be only 5 feet or less from the user, thus requiring a much shorter pole than would be required for the above ground scenario. In order to be properly prepared under such highly diverse and non-uniform conditions, user have been typically provided telescoping poles (sticks) or a selection of poles of varying lengths in order to properly accomplish various tasks without being required to go back to home-base to obtain a properly sized portable electrical power distribution line pole.

Utility line poles used by a user are required to be tested at regular intervals to ensure that the poles are free of defects and continue to provide an insulating barrier between the user and the electrical power distribution lines. OSHA/ASTM standards require utility line poles to be certified every two years using a test cage on full length (35 feet) at full voltage, or requires the pole to be tested in segments. ASTM standards further require a wet test with an optional dry test also being used to determine when a pole visibly dry on the surface has moisture and/or other contaminants not visible. These tests are done using a large testing device located at a testing facility. Unfortunately, users located in the field do not have a way to test the utility line poles that they have on the job during the two years between certification. As a result, a utility line pole may be damaged during use without the knowledge of the user and may no longer be suitable for use.

Accordingly, there is a need for a portable testing apparatus for utility line poles that allows a user to test a utility line pole in the field between certifications.

### BRIEF SUMMARY OF THE INVENTION

This need is addressed by the present invention, which provides a portable, battery-powered apparatus configured to quickly allow a user in the field (or the field office) to test a utility line pole prior to use.

### BRIEF DESCRIPTION OF THE DRAWINGS

The invention may be best understood by reference to the following description taken in conjunction with the accompanying drawing figures in which:

FIG. 1 is a front view of a portable testing apparatus;

FIG. 2 is a top perspective view of the portable testing apparatus of FIG. 1;

FIG. 3 is another top perspective view of the portable testing apparatus of FIG. 1;

FIG. 4 shows electronics of the portable testing apparatus of FIG. 1;

FIG. 5 is a bottom view of the portable testing apparatus of FIG. 1;

FIG. 6 shows a utility line pole being tested by the portable testing apparatus of FIG. 1;

FIG. 7 shows a utility line pole being tested by the portable testing apparatus of FIG. 1;

FIG. 8 is a bottom view of an alternative configuration of the portable testing apparatus of FIG. 1;

FIG. 9 shows a utility line pole being tested by the portable testing apparatus of FIG. 8.

FIG. 10 is an overall wiring schematic of the portable testing apparatus of FIG. 1; and

FIG. 11 is a wiring schematic of a control module of the portable testing apparatus of FIG. 1 interfaced with switches, batteries, a high voltage generator, electrodes, and a visual display.

### DETAILED DESCRIPTION OF THE INVENTION

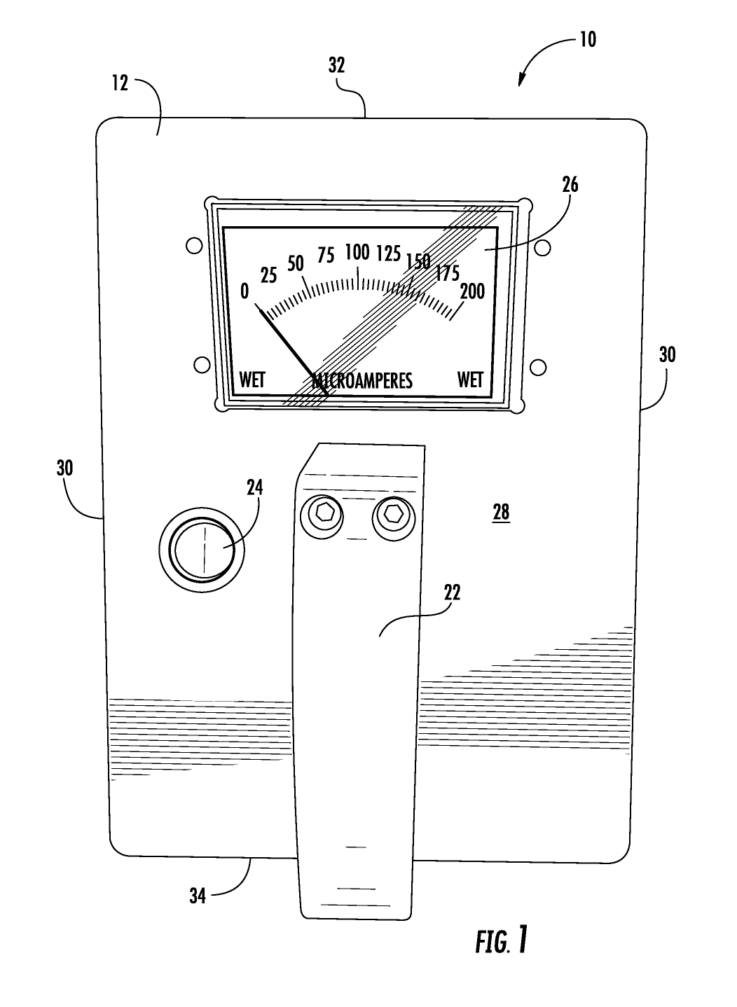

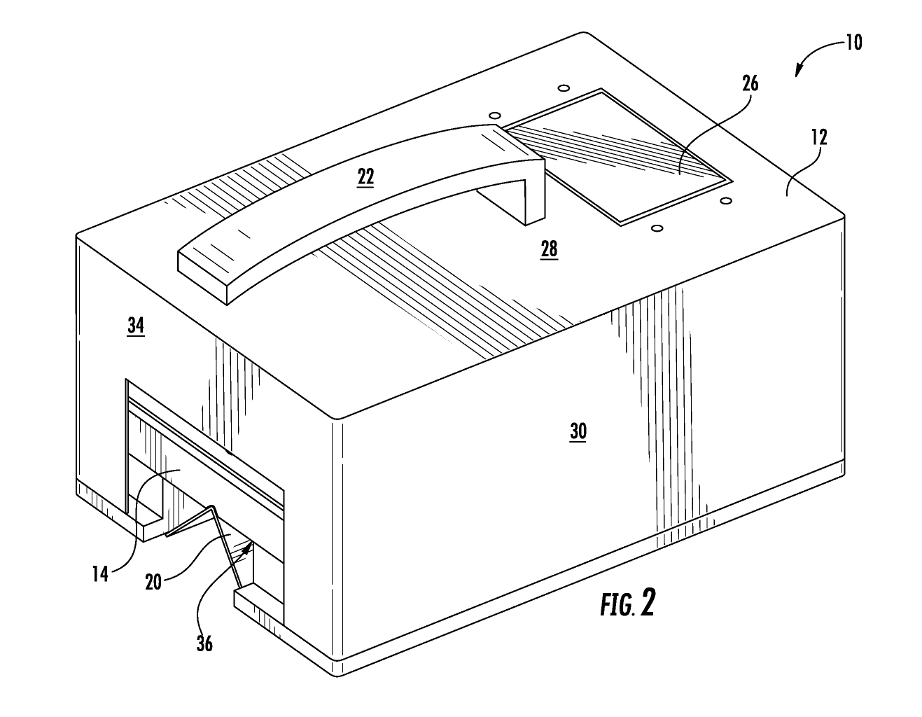

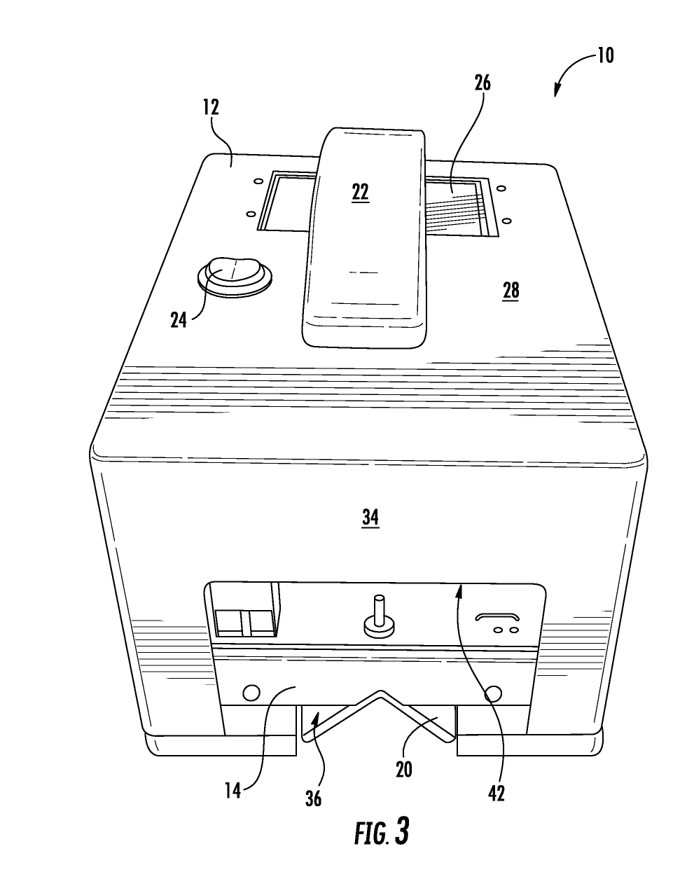

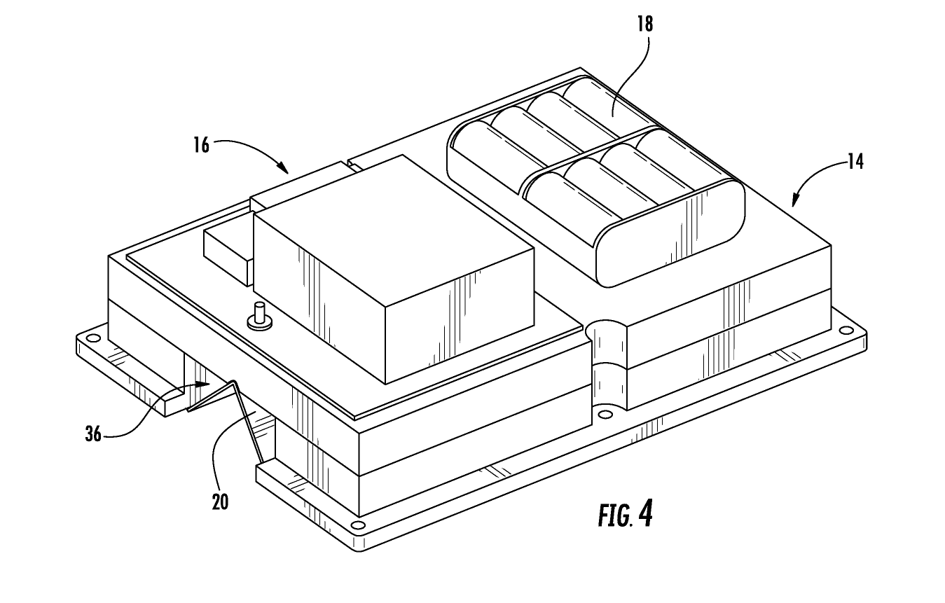

Referring to the drawings wherein identical reference numerals denote the same elements throughout the various views, FIGS. 1-4 illustrate an exemplary portable testing apparatus 10. The apparatus 10 includes a housing 12, a chassis 14 configured to support electronics 16 and a battery pack 18 (may be rechargeable), and one or more electrodes 20.

The housing 12 includes a handle 22 to allow an individual to carry the apparatus 10 into the field and/or on to a jobsite, a toggle switch 24 is configured to turn the apparatus 10 on/off and to toggle the apparatus 10 between a dry testing mode and a wet testing mode, and a visual display 26 (as shown, the display is a digital display of known types) configured to display data and operational modes to a user. As illustrated in FIG. 1, the display 26 shows an example “wet” mode display. By toggling the switch 24 from a right position to a left position, the display 26 can be changed to a “dry” mode display. It should be appreciated that the left and right positions may be reversed. It should also be appreciated that the microamperes scale changes when toggled between wet mode and dry mode and is calibrated accordingly to provide a user with an accurate reading when testing a device under test (DUT). By toggling the switch 24 to a center position, the apparatus 10 may be turned off. Switch 24 automatically causes the apparatus 10 to “zero” when switching between wet and dry modes.

As shown, the housing includes a front wall 28 (the handle 22, switch 24, and display 26 are located on the front wall 28), sidewalls 30, a first end wall 32, and a second end wall 34 that collectively define an interior volume and/or cavity 42 configured to receive the electronics 16, battery pack 18, and a portion of the chassis 14 therein.

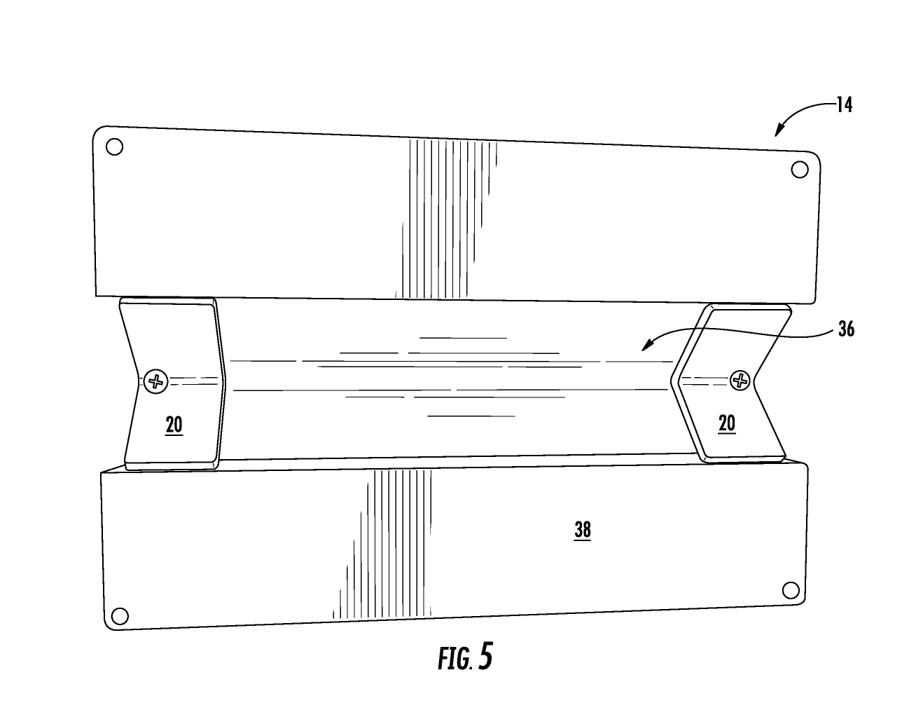

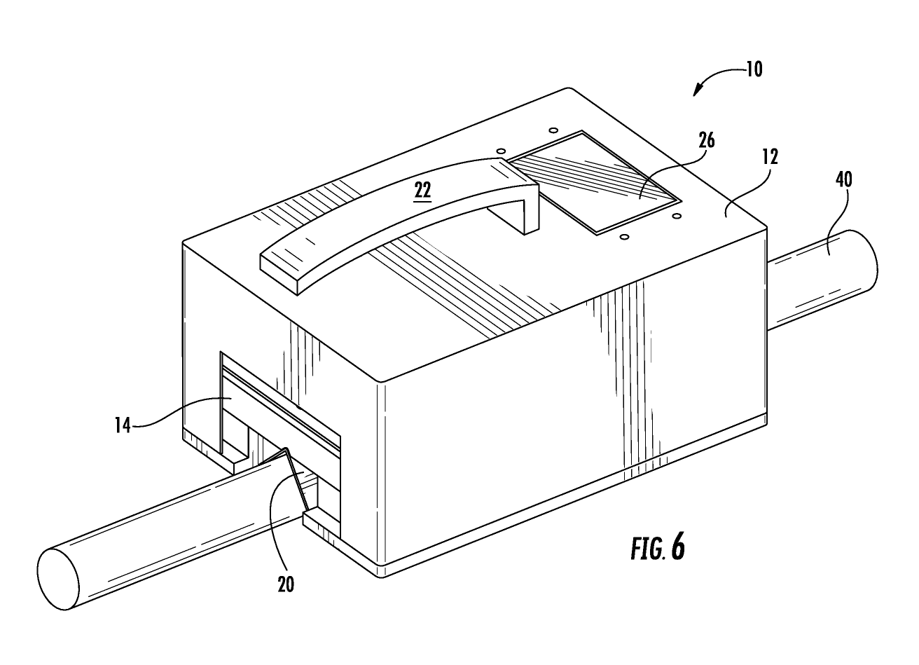

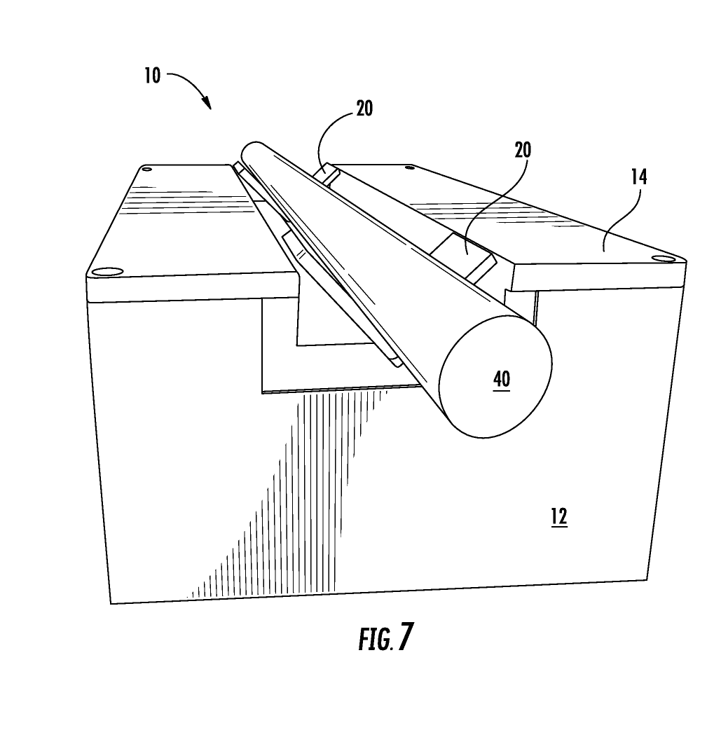

As illustrated in FIGS. 5-7, the chassis 14 includes a tunnel and/or channel 36 extending a length of a bottom 38 of the chassis 14. The tunnel 36 is configured to receive a DUT such as a utility line pole 40 therein for testing (See FIGS. 6 and 7). One or more electrodes 20 are positioned in the tunnel 36 to test the utility line pole 40 by imparting a voltage of 1.2 kV AC into the utility line pole 40. As shown, the electrodes 20 are formed of V-shaped conductive plates.

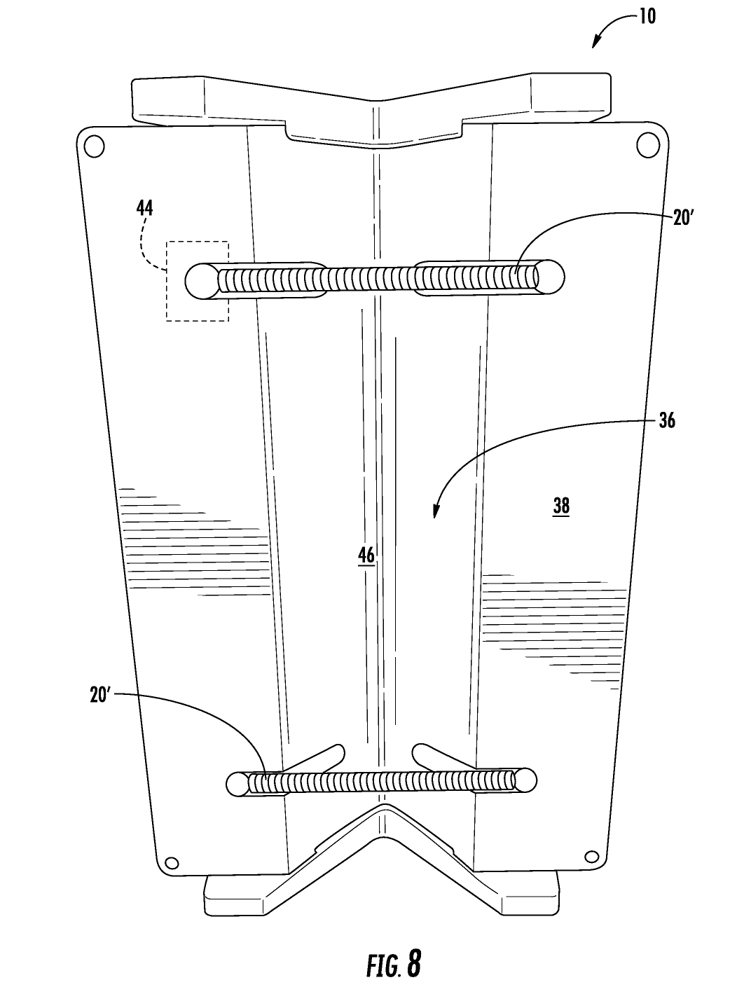

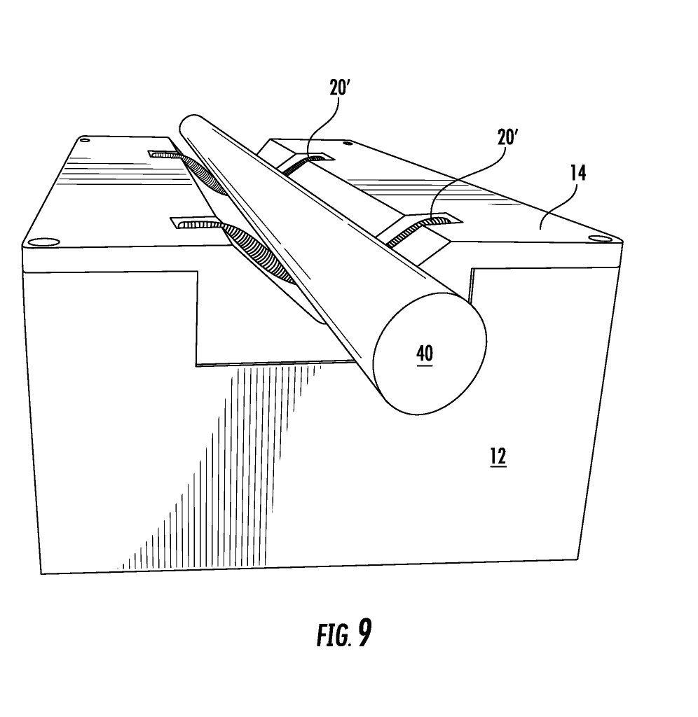

Alternatively, FIGS. 8-9, one or more electrodes 20′ may be used instead of or in combination with electrodes 20. As illustrated, electrodes 20′ are in the form of a flexible conductive device such as a spring. It should be appreciated that other suitable flexible conductive devices may be used. Electrodes 20′ permit the utility line pole 40 to be contacted by the electrodes 20′ in more than two locations—as shown, the electrodes 20′ provide a continuous contact to approximately half of the circumference of the utility line pole 40.

Additionally, by using flexible electrode 20′, a safety switch 44 may be employed. Safety switch 44 prevents the apparatus 10 from running a test without a DUT securely placed within the tunnel 36. More specifically, placing the apparatus 10 into a test mode using switch 24 will not automatically impart a voltage onto the electrodes 20′. Instead, after the apparatus has been placed into a test mode using switch 24, the user places the utility line pole 40 into the tunnel 36 and in contact with the electrodes 20′. The user then presses the apparatus 10 against the utility line pole 40 causing the electrodes 20′ to flex until they reach a test position. As illustrated, the test position occurs when the electrodes 20′ rest against a top wall 46 of the tunnel 36; however, it should be appreciated that the test position may occur prior to the electrodes 20′ making contact with the top wall 46. Once the electrodes 20′ reach the testing position, the safety switch 44 turns on the electronics 16 to activate testing of the utility line pole 40. This operation not only provides safety against inadvertent contact with “hot” electrodes, but it also preserves the battery pack 18 since the battery pack 18 will not be providing any power until the safety switch 44 turns on the apparatus 10.

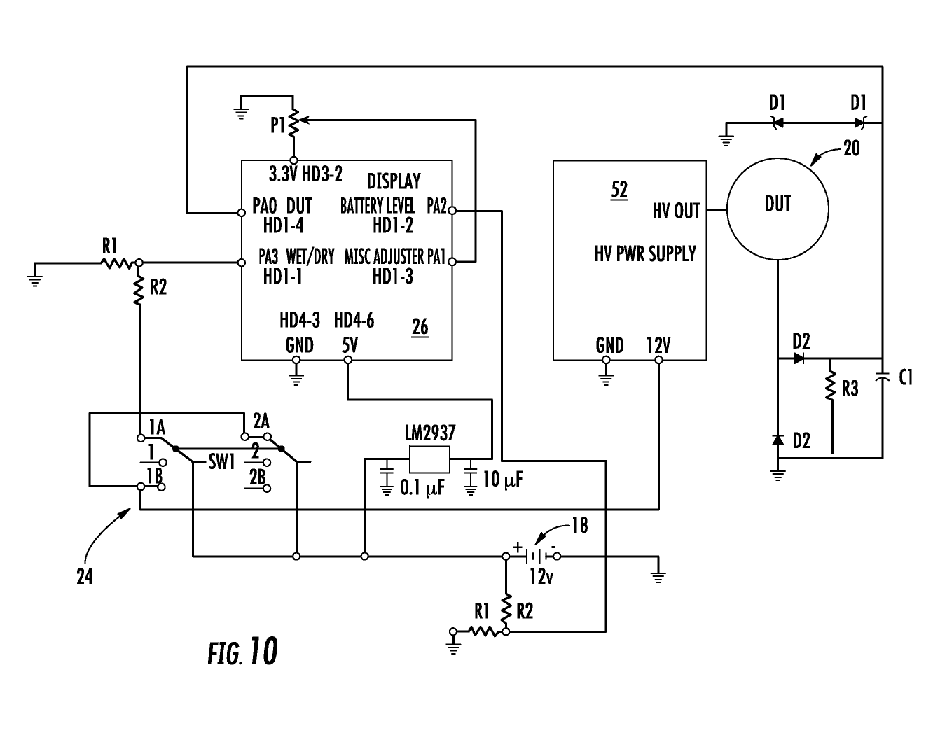

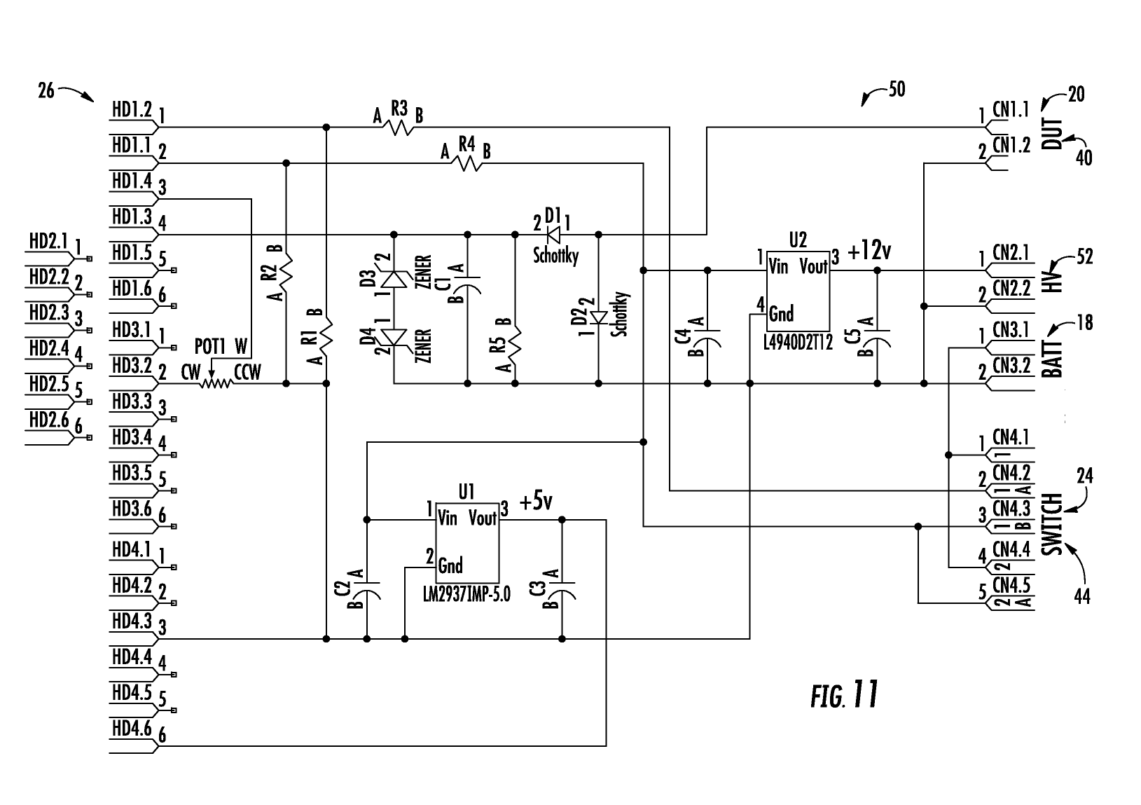

Referring now to FIGS. 10-11, the electronics 16 include a control module 50 and a high voltage generator 52. The generator 52 is powered by the battery pack 18 and generates 1.2 kV at 1.2 kHz alternating current (AC) from 12V direct current (DC) supplied by the battery pack 18. The 1.2 kV generated by the generator 52 is supplied directly to the electrodes 20 and/or 20′ to impart the 1.2 kV directly onto the DUT. AC must be used to detect subsurface defects in the utility line pole 40.

The control module 50 interfaces with the display 26 (HD1.1, HD1.2, etc.), switches such as switches 24 and 44, battery pack 18, and the high voltage generator 52 to control the operation of the apparatus 10. As illustrated, the module 50 includes a pair of voltage regulators (U1 and U2), a plurality of resistors (Rx), a plurality of diodes (Dx), and a pair of Zener diodes (D3 and D4). The Zener diodes D3, D4 are of particular significance because they are used to dump current to ground when excessive leakage current is created by a dead short and/or defects in the utility line pole 40 or when there is too much voltage. Further, the apparatus 10 automatically stops oscillating if it experiences a dead short to protect the generator 52.

The control module 50 is programmed to provide scaling for the apparatus 10. The control module 50 may be programmed using digital and/or analog inputs. ASTM standards require a dry test using 100 kV per foot with no heat or flashover permitted and a wet test using 75 kV per foot with not heat or flashover permitted and a conduction limit around 75 microamps. Such high testing voltages require a stationary power source capable of testing a 35 foot long DUT and a cage for safety. In order for the apparatus 10 to be portable, the apparatus 10 must be able to mimic a full scale test device.

Since the apparatus 10 is using 1.2 kV to test the utility line pole 40, the control module 50 must be capable of converting measured test values into corresponding values associated with full scale testing to provide accurate results consistent with a full scale test device. As a result, the control module 50 displays a microampere scale on the display 26 that mimics a full scale testing device. The microampere scale changes when switched between dry testing and wet testing which is done by toggling switch 24. When a test is being performed by the apparatus 10, the control module 50 converts the values measured during testing to full scale values and displays them on the display 26. Scaling may be done through algorithms and/or look-up tables programmed into the control module 50.

In use, a user toggles switch 24 to a first test mode, either a dry test mode or a wet test mode, and allows the apparatus 10 to automatically “zero” itself. The zero function of the apparatus is performed five times per second. Because the housing 12 and chassis 14 are grounded, the apparatus 10 is not frequency sensitive and any variation in zero is eliminated. With the mode selected and the apparatus 10 zeroed, the apparatus 10 is positioned over a section of a DUT such that the DUT is positioned in the tunnel 36 and in contact with the electrodes 20 and/or 20′. The apparatus 10 may be moved along the DUT after each test to test the entire length of the DUT.

Once the apparatus 10 is positioned over the DUT, the apparatus 10 is pressed down onto the DUT until a test position is reached. With the test position reached, the apparatus 10 begins conducting a test by imparting 1.2 kV at 1.2 kHz onto the DUT. Measurements are then conducted, i.e., voltage is measured across a known value resistor and current is computed using E=IR relationship. The voltage is measured every 200 microseconds and software of the apparatus 10 reports a digital “counts” or “steps” value (0-4096 counts over the full range). The control module 50 uses algorithms and/or a look-up table using an amps v. volts relationship for the known resistance to scale the output value to a full scale testing output value and displays that output value on the display 26.

When a “flashover” occurs the meter displayed on the display 26 will “peg out” to a maximum value. Additionally, when a dead short occurs, the apparatus 10 will stop oscillating. Once the user conducts testing in the first test mode, the user then toggles switch 24 into a second test mode (mode not selected in first test mode) and conducts testing in the same manner as described above. It should be appreciated that dry testing and wet testing are performed using different testing parameters, for example, wet testing requires the DUT to be sprayed with water to look for beads.

The foregoing has described a utility line pole testing apparatus and method. All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends any novel one, or any novel combination, of the features disclosed in this specification (including any accompanying claims, abstract and drawings), or to any novel one, or any novel combination, of the steps of any method or process so disclosed.

We claim:

1. A portable insulating pole testing apparatus, comprising:
at least one sensor electrode electrically connected to a high voltage generator;
a battery electrically connected to the high voltage generator; and
a visual display configured to provide a user with a visual indication of a condition of the insulating pole being tested, wherein the high voltage generator increases a voltage supplied by the battery to a pre-determined voltage and supplies the pre-determined voltage to the at least one sensor electrode, and wherein the insulating pole is pressed into contact with the at least one sensor electrode during testing to impart the pre-determined voltage into the insulating pole.

2. The apparatus according to claim 1, wherein the battery provides an output of 12 volts DC.

3. The apparatus according to claim 2, wherein the high voltage generator converts the battery output voltage to 1.2 kilovolts AC.

4. The apparatus according to claim 1, further including:
a chassis configured to support the high voltage generator and battery thereon, the chassis including a tunnel extending a length of the chassis and configured to receive a portion of an insulating pole therein; and
a housing having a cavity therein configured to receive the chassis, high voltage generator, and battery therein.

5. The apparatus according to claim 4, wherein the at least one electrode is positioned in the tunnel.

6. The apparatus according to claim 1, wherein the at least one sensor electrode is a V-shaped conductive plate.

7. The apparatus according to claim 1, wherein the at least one sensor electrode is a conductive spring.

8. A portable insulating pole testing apparatus, comprising:
a chassis having a top portion and a bottom portion, the chassis being configured to support electronics and a battery on the top portion of the chassis and a sensor electrode in a tunnel formed in the bottom portion and extending a length thereof;
a housing having a cavity therein configured to receive the top portion of the chassis, electronics, and battery therein, the housing including:
a visual display electrically connected to the electronics for providing a visual indication of testing results; and
a switch electrically connected to the electronics and configured to toggle the apparatus between a wet mode and a dry mode; and
wherein the electronics are electrically connected to the battery and the sensor electrode, the electronics generating a pre-determined voltage higher than a voltage provided by the battery and suppling the pre-determined voltage to the sensor electrode to impart the pre-determined voltage into an insulating pole positioned in the tunnel and pressed against the sensor electrode.

9. The apparatus according to claim 8, wherein the electronics generate a pre-determined voltage of 1.2 kilovolts AC from a voltage of 12 volts DC provided by the battery.

10. The apparatus according to claim 8, wherein the sensor electrode is a conductive spring configured to wrap around and provide uninterruptable contact to a portion of the insulating pole.

11. The apparatus according to claim 10, wherein the conductive spring flexes to provide uninterruptable contact with at least one-half of a circumference of the insulating pole.

12. The apparatus according to claim 8, further including a safety switch connected to the electronics, the safety switch preventing the electronics from supplying the pre-determined voltage to the sensor electrode until the insulating pole is pressed against the sensor electrode.

13. The apparatus according to claim 8, wherein the visual display mimics a scale of a full scale testing facility to provide a user with test results consistent with results provided by a full scale testing facility.

14. The apparatus according to claim 13, wherein the electronics scale measured test results to corresponding test values associated with a full scale testing facility and provides those results on the visual display.

15. A method of testing an insulating pole in the field, comprising the steps of:
providing a battery powered insulating pole testing apparatus;
placing the apparatus in a pre-determined test mode;
positioning the apparatus over a portion of an insulating pole to be tested;
pressing the apparatus against the portion of the insulating pole such that a sensor electrode makes contact with the insulating pole; and
performing a test on the portion of the insulating pole and displaying the results.

16. The method according to claim 15, further including the step of after reading the results, moving the apparatus to a new portion of the insulating pole and repeating the steps of pressing and performing.

17. The method according to claim 15, further including the step of placing the apparatus in a second pre-determined test mode and repeating the steps of positioning, pressing, and performing.

18. The method according to claim 15, wherein the apparatus automatically zeroes itself when placed in the pre-determined test mode.

19. The method according to claim 15, wherein the step of performing further includes the steps of:
using a high voltage generator to convert 12 volts DC from a battery to 1.2 kilovolts AC;
supplying the 1.2 kilovolts AC from the high voltage generator to the sensor electrode; and
imparting the 1.2 kilovolts AC onto the insulating pole to determine if the insulating pole contains any defects and/or contaminants.

20. The method according to claim 15, wherein the step of performing further includes the steps of:
measuring voltage every 200 microseconds; and
using an ampere versus volts relationship for a known resistor to scale an output value to a full scale testing output value and displaying the results on a visual display.
